(19) United States
(12) Patent Application Publication
(10) Pub. No.: US 2026/0215322 A1
(43) Pub. Date: Jul. 23, 2026

(54) ADVANCED PROCESSES FOR CU/POLYMER HYBRID BONDING FOR FINE-PITCH INTERCONNECTION AT PANEL LEVEL

(71) Applicant: GEORGIA TECH RESEARCH CORPORATION, Atlanta, GA (US)

(72) Inventors: Kyoung-Sik MOON, Atlanta, GA (US); Janagama Dasharatham GOUD, Atlanta, GA (US); Mohanalingam KATHAPERUMAL, Atlanta, GA (US); Pavithra Priyadharshini KUPPAKONE, Atlanta, GA (US); Madhavan SWAMINATHAN, Atlanta, GA (US)

(21) Appl. No.: 19/141,820

(22) PCT Filed: Dec. 21, 2023
(86) PCT No.: PCT/US2023/085541

§ 371 Date: Jun. 20, 2025

Related U.S. Application Data
(60) Provisional application No. 63/476,563, filed on Dec. 21, 2022.

(51) Int. Cl. H10W 72/90; H10W 72/00; H10W 90/00

(52) U.S. Cl. CPC H10W 72/934; H10W 72/01955; H10W 72/952; H10W 90/792; H10W 90/794

(57) ABSTRACT

An exemplary device and method that provides sub-10-um fine pitch interconnection between (i) a protruding pillar structure with Cu (e.g., nano-twinned Cu) on one surface having a B-stageable/Photo imageable polymer and (ii) a corresponding concave landing pad with Cu (e.g., nano-twinned Cu) on the other surface also having a same B-stageable/Photo imageable polymer, to provide for insertions for Cu-Cu bonding and B-stageable/Photo imageable polymers bonding. The Cu-Cu bonding and polymer bonding can facilitate a seamless bond interface at a low bonding temperature of 150° C. or even at room temperature (RT) with cleaned and improved surfaces.

### CROSS-REFERENCE TO RELATED APPLICATION

This international PCT application claims priority to, and the benefit of, U.S. Provisional Patent Application No. 63/376,562, filed Dec. 21, 2022, entitled “Advanced Processes for Cu/Polymer Hybrid Bonding for Fine-pitch Interconnection at Panel Level,” which is incorporated by reference herein in its entirety.

### BACKGROUND

Hybrid bonding is a permanent bond that combines an inorganic or polymer dielectric with embedded metal (Cu) to form interconnections, e.g., for advanced 3D device stacking, high-density IO, increased bandwidth, and reduced packaging volume. Hybrid bonding can provide signal delay and loss that are negligible among many benefits.

### SUMMARY

An exemplary device and method are disclosed that provides sub-10-μm fine pitch interconnection between (i) a protruding pillar structure with Cu (e.g., nano-twinned Cu) on one surface having a B-stageable/Photo imageable polymer and (ii) a corresponding concave landing pad with Cu (e.g., nano-twinned Cu) on the other surface also having a same B-stageable/Photo imageable polymer, to provide for insertions for Cu-Cu bonding and B-stageable/Photo imageable polymers bonding. The Cu-Cu bonding and polymer bonding can facilitate a seamless bond interface at a low bonding temperature of 150° C. or even at room temperature (RT) with cleaned and improved surfaces.

The low-temperature Cu-Cu bonding with pillar and concave on silicon substrate with and without polymer was demonstrated. The initiation of high shear stresses at the metal-metal contact interface can provide for high plastic deformation and strong bond formation.

The exemplary system and method provide for the fabrication of insertion Cu-Cu bonding in combination with low-temperature cure dielectric polymer/non-polymer dielectric and less oxidation-prone nt-Cu intersurface material for high plastic deformation and strong bond formation. In addition, both the pillar and the concave structures may include nt-Cu to facilitate improved and fast diffusion.

Fine pitch may be achieved by using photolithography using a maskless aligner tool and photosensitive polymers or by a laser drilling operation of non-photosensitive polymers to achieve concave structures or plasma dry etching of non-photosensitive polymers to accomplish concave structures with ultrafine pitches in the order of <5 μm. Furthermore, polymer hybrid bonding may include die/chip to substrate polymer-polymer to inorganic to polymer and hybrid inorganic-to-polymer bonding at low temperatures without using the typically required chemical and mechanical polishing (CMP). With glass substrates, the exemplary system and method can employ bonding by UV curing followed by annealing.

The exemplary method and system may be employed for panel-level fine pitch interconnection for advanced semiconductor packaging in heterogeneous integration.

The exemplary method and system may be employed for semiconductor bonding technology for easy scaling, low temperature, fast bonding, and high throughput.

The exemplary method and system may be employed to achieve panel-level bonding (larger than 300 mm).

In an aspect, a semiconductor device is disclosed comprising: a plurality of hybrid-bonding interconnection structures, each formed by placing (i) a nano-copper concave structure embedded in a first bonding polymer layer onto (ii) a non-planar protruding Cu structure embedded in a second polymer bonding layer, wherein a pitch distance between each of the plurality of hybrid-bonding interconnection structure is less than 5 μm.

In some embodiments, the nano-copper concave structure and the non-planar Cu structure form a Cu-Cu bonding at a low bonding temperature of less than 150° C.

In some embodiments, the non-planar protruding Cu structure forms a pillar for insertion into the nano-copper concave structure.

In some embodiments, the bonding polymer layer comprises a low-temperature cure dielectric polymer.

In some embodiments, the bonding polymer layer comprises a non-polymer dielectric.

In some embodiments, the nano-copper concave structure embedded in the dielectric is fabricated at least in part using photolithography and a maskless aligner tool in combination with a photosensitive polymer.

In some embodiments, the nano-copper concave structure embedded in the dielectric is fabricated at least in part using laser drilling of a non-photosensitive polymer.

In some embodiments, the first bonding layer is made of a first material, wherein the second bonding layer is made of a second material, wherein the first material and the second material are the same.

In some embodiments, the first material and the second material comprise a B-stageable/Photo imageable polymer or a photo imageable dielectric (PID).

In some embodiments, the first material and the second material comprise at least one of polyimide (PI), polybenzoxazole (PBO), and benzocyclobutene (BCB) (e.g., Cyclotene™). Other examples of PIDs include Benzocyclobutene-modified silsesquioxane (BCB-POSS), polyimide silsesquioxane (PI-POSS), epoxy, acrylated polymers, or any class of hybrid sol-gels.

In some embodiments, the plurality of hybrid-bonding interconnection structures are employed for chip-on-chip interconnect.

In some embodiments, the plurality of hybrid-bonding interconnection structures are employed for chip-on-wafer interconnect.

In some embodiments, the plurality of hybrid-bonding interconnection structures are employed for chip-on-glass panels interconnect.

In some embodiments, the plurality of hybrid-bonding interconnection structures are employed for chip-on-organic substrate interconnect.

In some embodiments, the plurality of hybrid-bonding interconnection structures are employed for wafer-on-wafer interconnect.

In some embodiments, the plurality of hybrid-bonding interconnection structures are employed for wafer-on-glass interconnect.

In some embodiments, the plurality of hybrid-bonding interconnection structures are employed for glass-on-glass interconnect.

In some embodiments, the nano-copper concave structure and the non-planar protruding Cu structure each includes (111) nano-twinned Cu surfaces having high surface diffusivity and low oxidation rate.

In another aspect, a method is disclosed to fabricate a first portion of an interconnection structure, the method comprising: coating a dielectric layer on a substrate; forming (e.g., via laser drilling or lithography) patterned portions of the dielectric layer; coating a patterned sacrificial layer over at least a portion of non-patterned portions; depositing a copper-based layer by glance angle deposition or electrodeposition to form a nano-copper concave structure embedded in a first bonding polymer layer; and removing the patterned sacrificial layer, wherein the nano-copper concave structure is contacted with a non-planar protruding Cu structure embedded in a second polymer bonding layer to form a hybrid-bonding interconnection structure.

In another aspect, a method is disclosed to fabricate a first portion of an interconnection structure, the method comprising: coating a dielectric layer on a substrate; removing, via a laser machining operation, portions of the dielectric layer to form a nano-copper concave structure embedded in a first bonding polymer layer; wherein the nano-copper concave structure is contacted with a non-planar protruding Cu structure embedded in a second polymer bonding layer to form a hybrid-bonding interconnection structure.

In some embodiments, the first portion of an interconnection structure is bonded to a second portion of the interconnection structure, the second portion having a nano-copper structure embedded in a bonding layer.

In some embodiments, the nano-copper concave structure has a pitch of 5 um or less to another nano-copper concave structure.

In some embodiments, the first bonding layer is made of a first material, wherein the second bonding layer is made of a second material, wherein the first material and the second material are the same.

In some embodiments, the first material and the second material comprise a B-stageable/Photo imageable polymer or a photo imageable dielectric (PID), preferably, at least one of: polyimide (PI), polybenzoxazole (PBO), benzocyclobutene (BCB). Other examples of PIDs include, Benzocyclobutene-modified silsesquioxane (BCB-POSS), polyimide silsesquioxane (PI-POSS), epoxy, acrylated polymers, or any class of hybrid sol-gels.

In some embodiments, the plurality of hybrid-bonding interconnection structures are employed for chip-on-chip interconnect, chip-on-wafer interconnect, chip-on-glass panel interconnect, chip-on-organic substrate interconnect, wafer-on-wafer, wafer-on-glass, or glass-on-glass interconnect.

In some embodiments, the nano-copper concave structure and the non-planar protruding Cu structure each includes (111) nano-twinned Cu surfaces having high surface diffusivity and low oxidation rate.

In another aspect, an interconnection structure is disclosed having been formed by placing (i) a nano-copper structure embedded in a bonding layer onto (ii) a non-planar Cu structure.

In some embodiments, the nano-copper concave structure and the non-planar Cu pillar structure form a Cu-Cu bonding at a low bonding temperature (e.g., room temperature to 200° C., e.g., 150° C.), each having a pitch less than 5 μm.

In some embodiments, the bonding layer comprises a low-temperature cure dielectric polymer.

In some embodiments, the dielectric comprises a non-polymer dielectric.

In some embodiments, the nano-copper concave structure embedded in the dielectric is fabricated at least in part using photolithography and a maskless aligner tool in combination with a photosensitive polymer.

In some embodiments, the nano-copper concave structure is fabricated at least in part using laser drilling of a non-photosensitive polymer.

In some embodiments, the nano-copper concave structure is fabricated by a dry plasma etch process using gas phase etchants.

In some embodiments, the first portion of an interconnection structure is bonded to a second portion of the interconnection structure, the second portion having a nano-copper structure embedded in a bonding layer.

### BRIEF DESCRIPTION OF THE DRAWINGS

The skilled person in the art will understand that the drawings described below are for illustration purposes only.

FIG. 1 shows an example Cu-Cu Polymer-Polymer interconnect with Cu-Cu and B-stageable/photo imageable polymer hybrid bond in accordance with an illustrative embodiment.

FIG. 2A shows the exemplary Cu-Cu Polymer-Polymer interconnect in relation to a solder attachment in accordance with an illustrative embodiment.

FIG. 2B shows a plot of the signal delay/loss characteristics of the Cu-Cu Polymer-Polymer interconnect over micro-bump and solder bump technologies.

FIG. 3A shows an example method of fabrication of the example Cu-Cu Polymer-Polymer interconnect.

FIG. 3B shows the operation employing gray-scale mask equipment, maskless equipment, and laser machining equipment.

FIG. 3C shows an example method for polymer hybrid bond process flow in accordance with an illustrative embodiment.

FIG. 3D show example chemical structures for the polymer coating of the Cu-Cu Polymer-Polymer interconnect in accordance with an illustrative embodiment.

FIGS. 4A, 4B, and 4C each shows measurements via an optical microscope of a fabrication of a concave structure in two different photo-imageable dielectrics (PIDs) using a maskless aligner.

FIGS. 5A and 5B each shows measurements via optical microscope of the fabricated concave structure in two different non-PIDs using a femtosecond laser.

### DETAILED SPECIFICATION

To facilitate an understanding of the principles and features of various embodiments of the present invention, they are explained hereinafter with reference to their implementation in illustrative embodiments.

Hybrid bonding is a permanent bond that combines an inorganic or polymer dielectric with embedded metal (Cu) to form interconnections that can enable advanced 3D device stacking, provide high density I/O and Increased Bandwidth, enable sub-10 μm pitch, reduce packaging volume, increase functionality, employ lower power consumption, and provide a smaller footprint. The method can be implemented in an efficient fabrication process for industrial production.

### Example Cu-Cu and B-stageable/Photo Imageable Polymer Hybrid Bonding

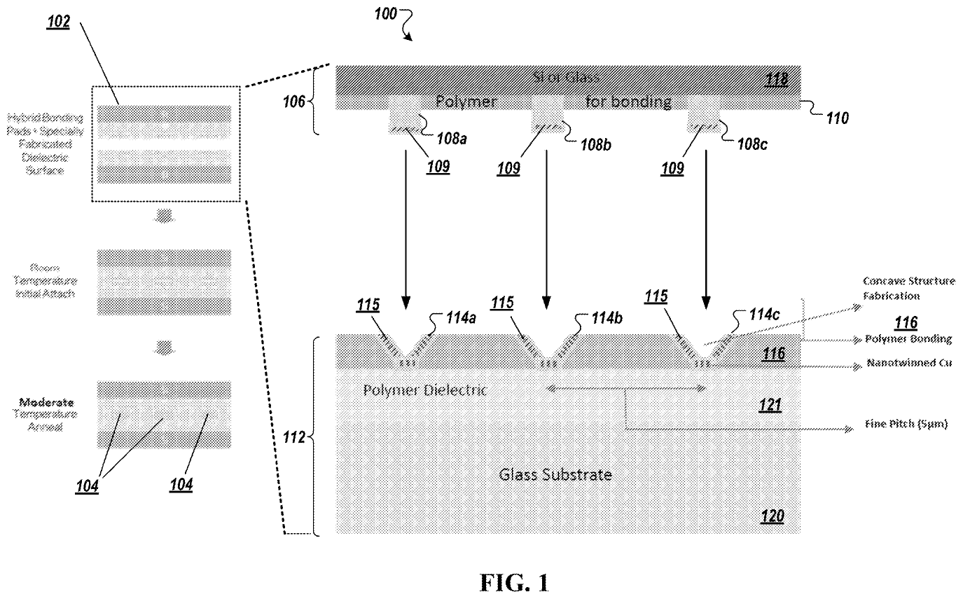

FIG. 1 shows an example Cu-Cu Polymer-Polymer interconnect 100 (for a device 102) with Cu-Cu and B-stageable/photo imageable polymer hybrid bond 104, facilitated by creep on (111) surfaces, in accordance with an illustrative embodiment. The Cu-Cu Polymer-Polymer interconnect 100 is fabricated through a laser machining operation to provide higher throughput and finer structures.

In the example shown in FIG. 1, the Cu-Cu Polymer-Polymer interconnect 100 is provided between (i) a first substate 106 having a non-planar nano Cu structures 108 shown as protruding pillar structures 108a, 108b, 108c formed over a bonding substrate 110, e.g., B-stageable/Photo imageable polymer (shown as “Polymer for bonding” 110) and (ii) a second substrate 112 having corresponding concave landing pads 114 (shown as 114a, 114b, 114c) formed over another bonding polymer substrate 116, e.g., B-stageable/Photo imageable polymer (shown as “Polymer Bonding” 116).

The protruding pillar structures 108a, 108b, 108c align to the corresponding concave landing pads 112a, 112b, 112c to provide for insertions for Cu-Cu bonding and B-stageable/Photo imageable polymers low-temperature bonding. The non-planar Cu structures (108, 114) can be formed with nano-twinned Cu (nt-Cu) 109, 115 for insertion bonding. The low bonding temperature can occur at 150° C. (with slight heating) or even at room temperature (RT) (without heating). Room temperature refers to the environmental temperature for a clean room where the device would be fabricated, e.g., 21 degrees Celsius or 69.8 degrees Fahrenheit. The bonding polymer substrates 110, 116 serve like a glue for polymer-polymer bonding along with the protruding pillar structures 108a, 108b, 108c and concave landing pads 112a, 112b, 112c with the Cu-Cu bonding. The polymer material can provide high adhesive strength to adhere to different substrates, such as printed circuit boards. The nano-twinned Cu can be formed via electroplating or sputtering to provide (111) nano-twinned Cu surfaces with high surface diffusivity and low oxidation rate for that plane (111).

The first bonding substrate 110 and the second bonding polymer substrate 116 are formed over the structures of the devices. In the example shown in FIG. 1, the first bonding substrate is formed over silicon or glass substrate 118, and the second bonding substrate is formed over a glass substrate 120 through a polymer dielectric 121. Other materials can be used to which the B-stageable/Photo imageable polymer bonding substrate 110, 116 can be formed.

The polymer dielectric 112 is formed to provide an interface layer with low Young's Modulus, low CTE, low solubility in H₂O, and low moisture absorption. The bonding energy can be greater than 2.5 J/m², and the die shear strength can be greater than or equal to 50 MPa, in some embodiments.

The polymer bonding substrate 110, 116 can be formed in a planar manner without chemical-mechanical planarization (CMP).

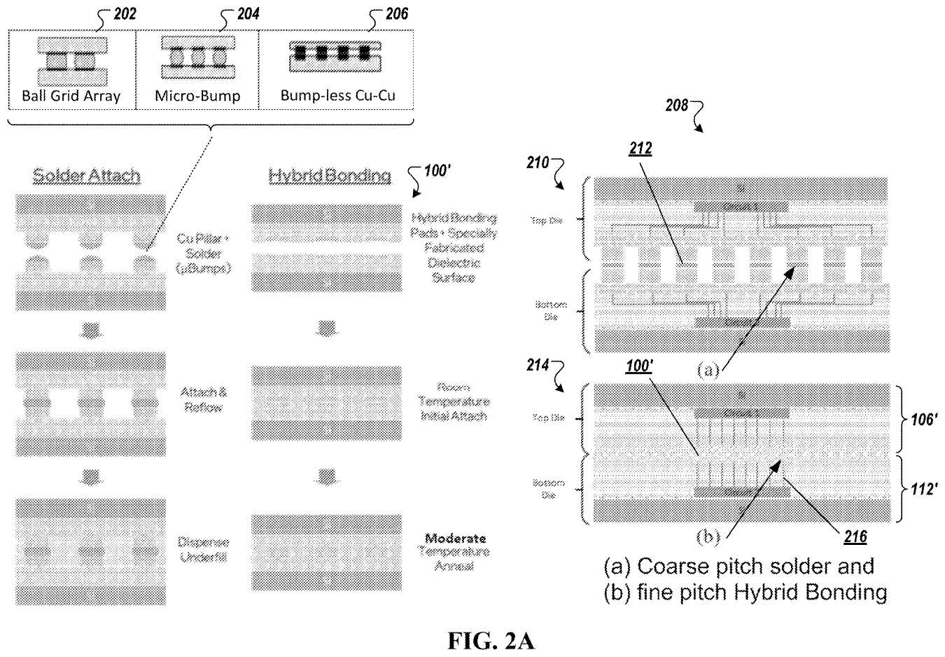

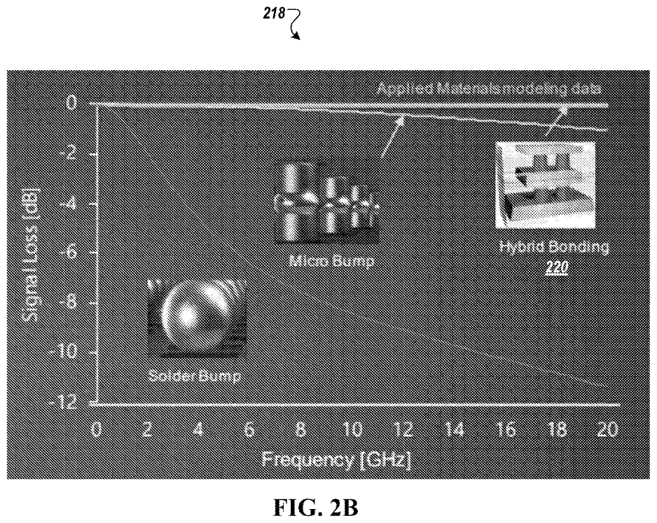

FIG. 2A shows the exemplary Cu-Cu Polymer-Polymer interconnect 100 (shown as 100′) in relation to solder attachments (202, 204, 206). As compared to ball grid arrays 202, micro-bumps 204, and bump-less Cu-Cu bonds 206, the Cu-Cu Polymer-Polymer interconnect 100′ provides finer pitch via hybrid bonding 104. A ball grid array 202, e.g., for package-on-package interconnect, can have a size of around 450 μm and a pitch of around 1000 μm. A micro-bump 204, e.g., for chip-on-chip, chip-on-wafer, chip-on-glass panel, or chip-on-organic substrate interconnect, can have a size between 60 μm and 120 μm and a pitch between 120 μm and 240 μm. A bump-less Cu-Cu interconnect 206, e.g., for chip-on-wafer, chip-on-glass panel, chip-on-organic substrate, wafer-on-wafer, wafer-on-glass, or glass-on-glass interconnect, as a 2.5D integration can have a size of less than 10 μm and a pitch of less than 20 μm. In contrast, the exemplary Cu-Cu Polymer-Polymer interconnect (e.g., 100, 100′) can provide a sub-10-μm pitch that would allow for higher bump density; FIG. 1 shows an example pitch being, e.g., around 5 μm.

Diagram 208 shows a device 210 having advanced solder interconnects 212 at 10 and 20 μm pitch to provide more than 10,000 connections/mm² using 2.5 integration technology, reproduced from Elsherbini, Adel. “Advancing 3D Packaging for Heterogenous Systems Integration.” Electrochemical Society Meeting Abstracts 242. No. 17. The Electrochemical Society, Inc., 2022, as a comparison to the exemplary Cu-Cu Polymer-Polymer interconnect 100′. Similar coarse structures are described in Yang, Yu-Tao, et al. “Low-temperature Cu-Cu direct bonding using pillar-concave structure in advanced 3-D heterogeneous integration.” IEEE Transactions on Components, Packaging and Manufacturing Technology 7.9 (2017): 1560-1566.

In contrast, diagram 208 shows a device 214 formed having the exemplary Cu-Cu Polymer-Polymer interconnect 100′ having finer sub-10-μm pitch. The exemplary Cu-Cu Polymer-Polymer interconnect 100′ thus increases the bump density by at least three orders of magnitude over the 2.5 integration technology shown in device 210 and 3D integration technology noted above. Indeed, the signal delay/loss using the Cu-Cu Polymer-Polymer interconnect 100, from the increased bump density, can be made almost negligible as the increase in the bump density can allow for 1:1 routing 216 between substrates 106, 112 (shown as 106′ and 112′) while allowing for a more straightforward design and design layout.

FIG. 2B shows a plot 218 of the signal delay/loss characteristics 220 of the Cu-Cu Polymer-Polymer interconnect 100′ (shown as “Hybrid bonding” 220) over micro-bump and solder bump technologies.

The exemplary Cu-Cu Polymer-Polymer interconnect (e.g., 100, 100′) can provide efficient hybrid bonding conditions with a clean surface with no impurities and particles. The Cu surfaces (pillar and concaves) can be formed without Cu oxides to provide alignment. The interconnect can be formed void-free in the Cu-Cu and polymer-polymer bonding surfaces to provide flat surfaces with minimum height variation and surface roughness. Passivation of the Cu and polymer surfaces can be employed as needed.

The protruding pillar structures 108 can be formed with geometries, such as circular pillars, trapezoids, or row structures, to be optimally shaped with the landing pads to facilitate guided insertions with proper alignment. Examples of such geometries are described in T. C. Chou et al., “Investigation of Pillar-Concave Structure for Low-Temperature Cu-Cu Direct Bonding in 3-D/2.5-D Heterogeneous Integration,” in IEEE Transactions on Components, Packaging and Manufacturing Technology, vol. 10, no. 8, pp. 1296-1303, Aug. 2020, doi: 10.1109/TCPMT. 2020.3004969, which is incorporated by reference herein. Additional examples of the process of fabricating the pillar structure 108 may be found in Yang, Yu-Tao, et al. “Low-temperature Cu-Cu direct bonding using pillar-concave structure in advanced 3-D heterogeneous integration.” IEEE Transactions on Components, Packaging and Manufacturing Technology 7.9 (2017): 1560-1566, which is incorporated by reference herein.

### Example Method of Fabrication

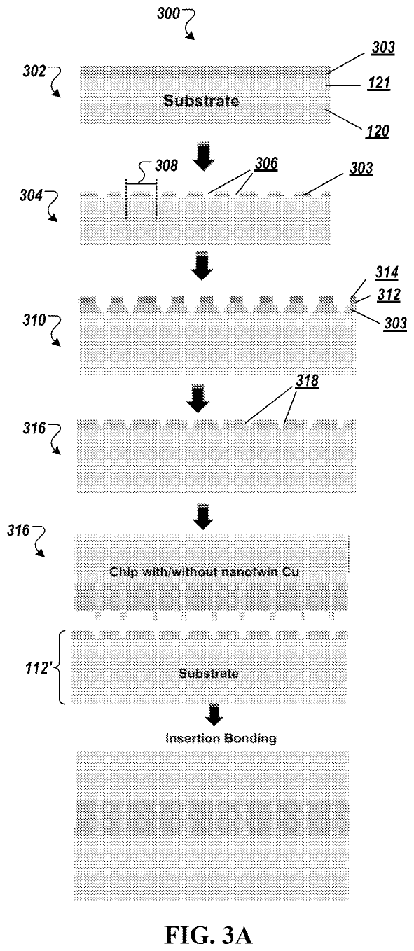

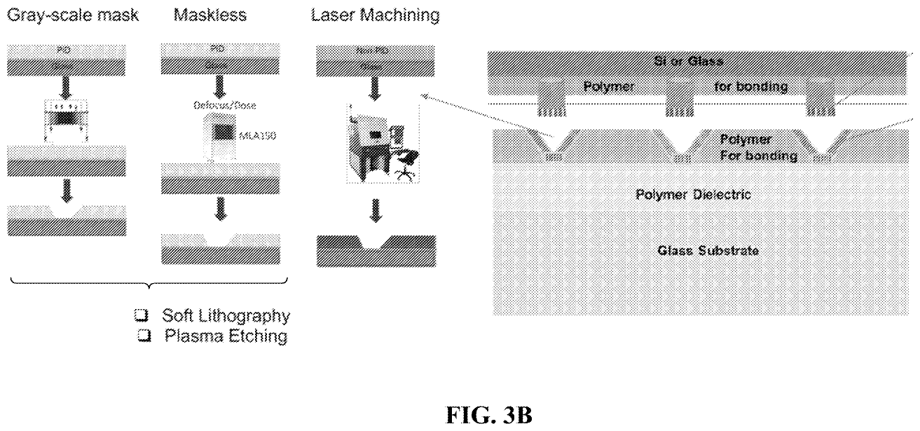

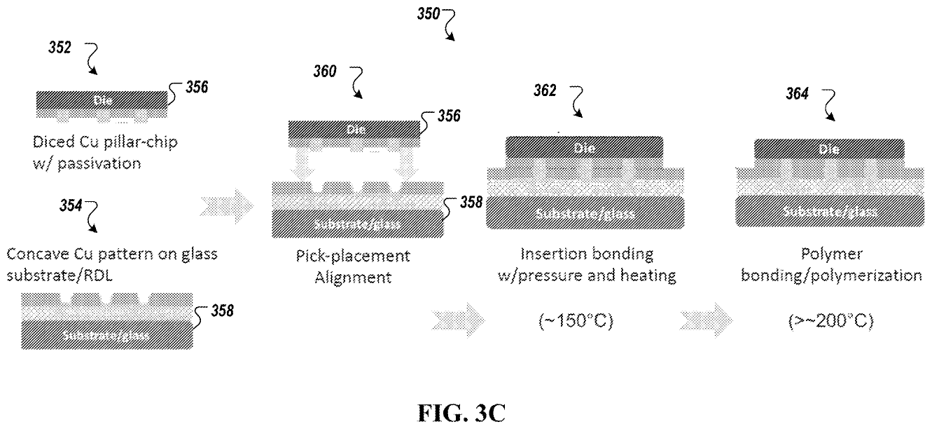

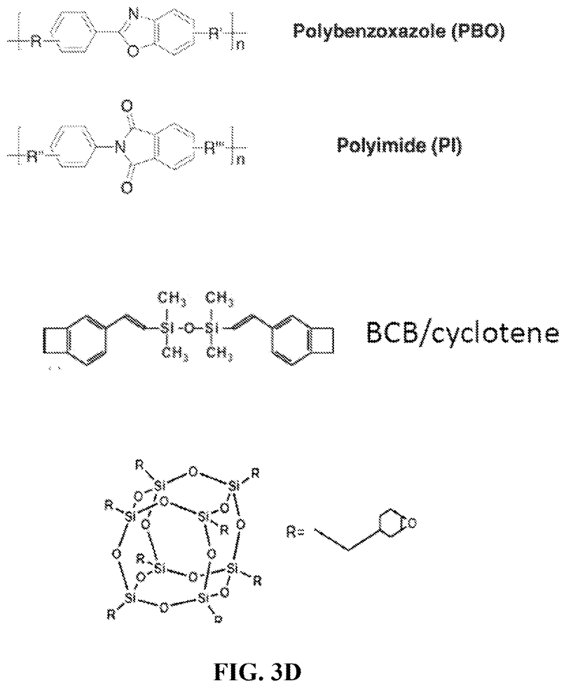

FIG. 3A shows an example method 300 of fabrication of the example Cu-Cu Polymer-Polymer interconnect 100. The method 300 includes fabricate an interconnection structure by coating a dielectric layer on a substrate; forming (e.g., via laser drilling or lithography) patterned portions of the dielectric layer; coating a patterned sacrificial layer over at least a portion of non-patterned portions; depositing a copper-based layer by glance angle deposition or electrodeposition to form a nano-copper concave structure embedded in a first bonding polymer layer; and removing the patterned sacrificial layer, wherein the nano-copper concave structure is contacted with a non-planar protruding Cu structure embedded in a second polymer bonding layer to form a hybrid-bonding interconnection structure.

Alternatively, the interconnection structure can be fabricated by laser machining by coating a dielectric layer on a substrate; and removing, via a laser machining operation, portions of the dielectric layer to form a nano-copper concave structure embedded in a first bonding polymer layer; wherein the nano-copper concave structure is contacted with a non-planar protruding Cu structure embedded in a second polymer bonding layer to form a hybrid-bonding interconnection structure.

In the example shown in FIG. 3A, method 300 includes forming (302) a dielectric coating 121 and polymer coating 303 on a substrate 120.

The polymer coating 303 may be a B-stageable/Photo imageable polymer or a photo imageable dielectric (PID) such as polyamide (PI), poly benzoxazole (PBO), Benzocyclobutene (BCB) or other Cyclotene™. Other examples of PIDs include, Benzocyclobutene-modified silsesquioxane (BCB-POSS), polyimide silsesquioxane (PI-POSS), epoxy, acrylated polymers, and hybrid sol-gels. Other build-up materials can be used, e.g., that have physical properties compatible with concave structure fabrication and bonding process (e.g., patternable, photoreactive, or drillable). The material should be tunable for dimension, thickness (spin-on or dry film), shrinkage, and planarization/roughness. The material should be compatible with bonding process polymerization chemistry at interfaces/bulk and have suitable material properties for adhesion, barrier property, low outgassing, thermomechanical properties for low stress (CTE, modulus, elongation), distribution of breakdown voltage (BDV), and electromagnetic (EM). FIG. 3D shows example chemical structures for the polymer coating 303.

Method 300 then includes forming (304) vias 306 (arrows shown for two examples) in the polymer coating 303; the vias are formed having a pitch (308) of less than 10-μm, e.g., less than 5-μm. The vias 306 may be formed (i) using soft lithography operation followed by plasma etching or (ii) using laser machining/drilling. FIG. 3B shows the operation employing gray-scale mask equipment, maskless equipment, and laser machining equipment.

In some embodiments, the pitch is around 1 μm, 2 μm, 3 μm, 4 μm, or 5 μm. In some embodiments, the pitch is less than 1 μm.

Depositing the copper-based layer can comprise any suitable method, such as, for example, thermal oxidation, electroplating by selected additive materials, lithographic deposition, electron beam deposition, thermal deposition, spin coating, drop-casting, zone casting, dip coating, blade coating, spraying, vacuum filtration, chemical vapor deposition (CVD), atomic layer deposition (ALD), physical vapor deposition (PVD), sputtering, pulsed layer deposition, molecular beam epitaxy (MBE), evaporation, or combinations thereof.

Referring still to FIG. 3A, Method 300 then includes forming (310) a pattern for the concave structure growth. In the example, a seed layer 312 and photoresist lamination 314 are deposited. The formed layers are then cured and exposed to UV exposure to form the pattern for the concave structures.

Removing the patterned sacrificial layer can comprise any suitable method, such as, for example, thermal etching, plasma etching, chemical etching, wet etching, solvent removal, or a combination thereof.

Method 300 then includes forming (316) a nanotwinned Cu deposited structure, e.g., by Glance Angle deposition (GLAD) or electrodeposition, in the exposed, etched, or laser machined regions of the polymer coating 303, to form the nano-twinned concave structure 318, thus forming the bonding polymer substrate 116. GLAD sputtering/PED of nt-Cu can be employed to provide interfacial material for copper pillars and concave structures. The GLAD process can provide Cu-Cu bonding by creep on (111) surfaces of nt-Cu. nt-Cu fabrication by electroplating is described in Hasegawa, Madoka, et al. “Orientation-controlled nanotwinned copper prepared by electrodeposition.” Electrochimica Acta 178 (2015): 458-467, which is incorporated by reference herein. Alternatively, nt-Cu fabrication by sputtering using GLAD is described in Yang, Zi-Hong, Po-Ching Wu, and Tung-Han Chuang. “Effects of substrate bias on the sputtering of high density (111)-nanotwinned Cu films on SiC chips.” Scientific Reports 12.1 (2022): 15408, which is incorporated by reference herein.

Once formed, the substrate 112 (shown as 112′) with the bonding polymer substrate 116 and concave structures can be placed in aligned contact with the corresponding substrate having the pillars or nano-twinned Cu pillars. In some embodiments, the hybrid bond can be formed at low temperatures (e.g., less than 200° C.) and quickly (e.g., less than 10 minutes).

Polymers for the process would have physical properties compatible with concave structure fabrication and bonding process, metallization, stiffness, etc. The polymer should have fast polymerization properties at interfaces/bulk and have suitable barrier properties, low outgassing, and low stress (CTE, modulus, elongation).

FIG. 3C shows an example method 350 for polymer hybrid bond process flow. In FIG. 3C, a diced Cu pillar chip 356 with passivation has been fabricated 352 and a glass substrate 358 having a concave Cu pattern on polymer is fabricated 354. Method 350 then includes contacting (360) the pillar chip 356 with the concave Cu pattern on polymer 354 via a pick-placement alignment process. Method 350 then includes performing insertion bonding (362) the pillar chip 356 and concave Cu pattern on polymer 354 via application of pressure and heat (e.g., around 150° C.). Other temperatures can be employed as described herein. Method 350 then includes performing polymer bonding and polymerization via a second heating operation (e.g., around 200° C. or greater).

### Experimental Results and Additional Examples

Several experiments have been conducted to fabricate and characterize a Cu-Cu Polymer-Polymer interconnect. The rapid development of packaging technology, decreasing size fine pitch interconnects and increasing Joule heat make a great challenge on the mechanical properties and thermal stability of copper interconnected materials. Nanotwinned copper with desirable characteristic features was evaluated and determined to be suitable for the next generation interconnected materials. Cu-Cu bonding enabled by creep on (111) surfaces of nanotwinned Cu (nt-Cu) can provide high surface diffusivity, low oxidation rate of that particular plane(111), can provide high electroconductivity, high electromigration resistance, and enhanced strain rate sensitivity of nanotwinned Cu with temperature, which was higher than that found in coarse-grained Cu, high mechanical strength, and resistance of the growth of interfacial intermetallic compounds (IMCs).

The experiments formed several concave structures by two approaches: maskless aligner and laser machining

Maskless Aligner. In a first set of experiments, a maskless aligner tool was used to form the concave structure through direct writing/exposure (no need to use a physical mask) of the photosensitive polymer by adjusting the defocus conditions during the laser exposure of a photo-imageable dielectric material. Laser based methods to formation of concave structure was achieved with any photo-imageable dielectric (PID) material by adjusting the defocus conditions maskless aligner technique. The PID material was laminated on a glass/silicon wafer/organic substrates that are in a wafer or a square panel form. The laser exposed region of the polymer was cross-linked, and the unexposed polymer region was removed by developing the polymer material in a solvent, i.e., propylene glycol methyl ether acetate (PGMEA), for 45-60 seconds. The resultant film was dried by blowing air, though nitrogen could also be used.

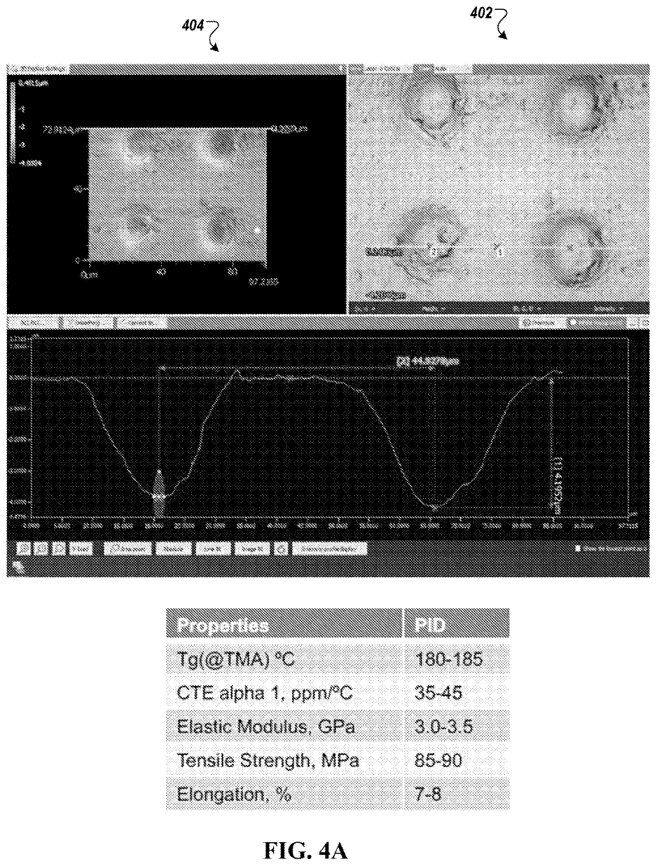

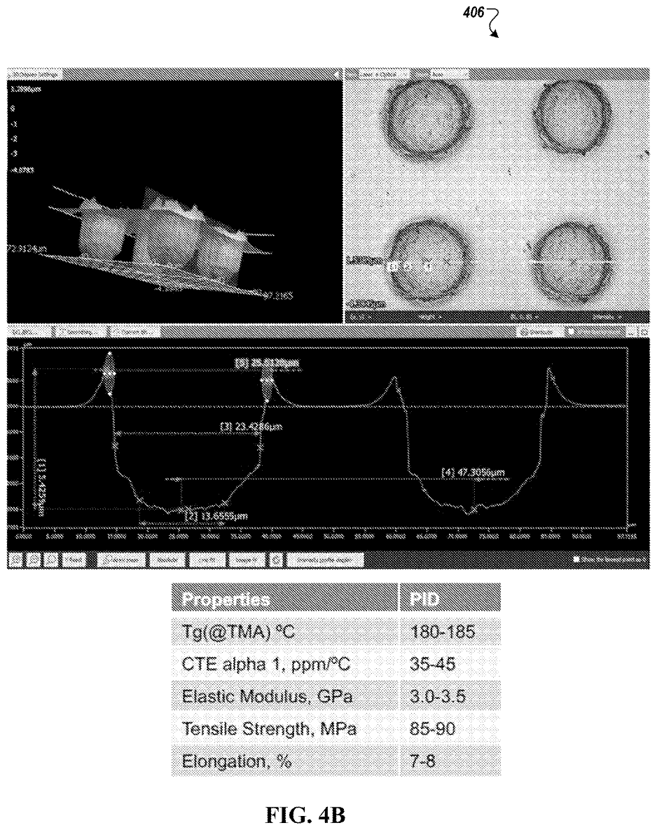

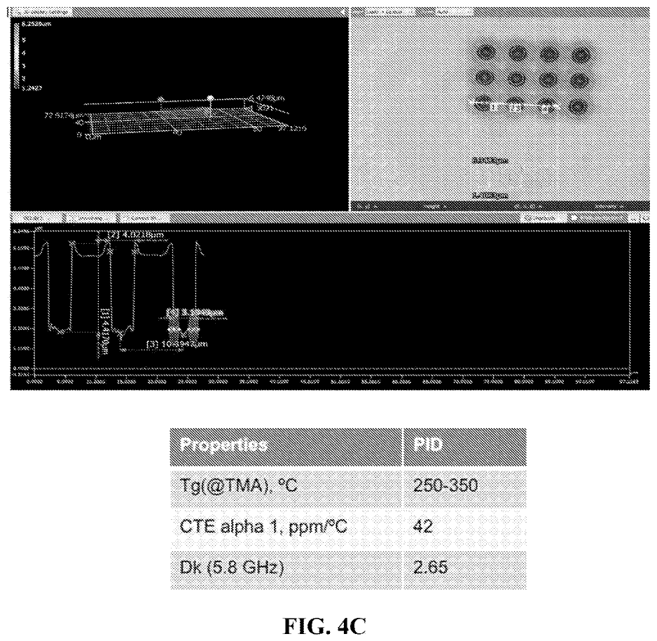

FIGS. 4A and 4B each shows measurements via optical microscopy of fabricated concave structure in a photo-imageable dielectric (PID) using a maskless aligner. In the optical image 402, a fabricated concave structure is shown to have a pitch of about 0.248 μm×2. Image 404 shows the fabricated concave structure having a depth of about 4.4 μm (per measure of −4.0303 μm and 0.4615 μm for the top and bottom surface of the concave structure). The PID is an HR100 (dry film for 5 μm). The PID had an exposure dose of 140 mJ/cm². FIG. 4A shows the mechanical characterization properties of the PID.

FIG. 4C shows another example of a fabricated concave structure. The film thickness of the PID material used was 5-80 micron. The device in FIG. 4C included a 5-micron PID material that was spin-coated on a Ti/Cu seed layer deposited glass substrate. The film was then exposed to a laser at 375 nm wavelength in a maskless aligner tool to form the concave structure. The sample was then developed in PGMEA for 60 seconds, and then dried by blowing with dry air (though Nitrogen could also have been used). The required angle of the concave structure was achieved by using the right defocus and dose conditions.

FIG. 4C shows measurements via optical microscopy of the fabricated concave structure in another photo-imageable dielectric (PID) using a maskless aligner. In image 406, a fabricated concave structure is shown to have a diameter size of about 5.9 μm. The PID is a BCB (for 5 μm). The PID had an exposure dose of 200 mJ/cm². FIG. 4C also shows the mechanical characterization properties of the PID.

Laser Machining. In another experiment, the concave structure was formed by laser ablation of the polymer material after the polymer is laminated on a glass substrate. In the example, a polymer film with a thickness of 15-30 micron was laminated at 90° C. and 1 MPa using a vacuum laminator. The film was cured, and the polymer was then ablated with a laser (wavelength: 1050 nm, pulse width: 200 femtoseconds). The debris in the cavity was cleaned by a wet process (solvent rinse), though other cleaning by means of a plasma descum process can be used. One advantage of this method is that any polymer laminated on a glass substrate can be ablated to form the concave cavity.

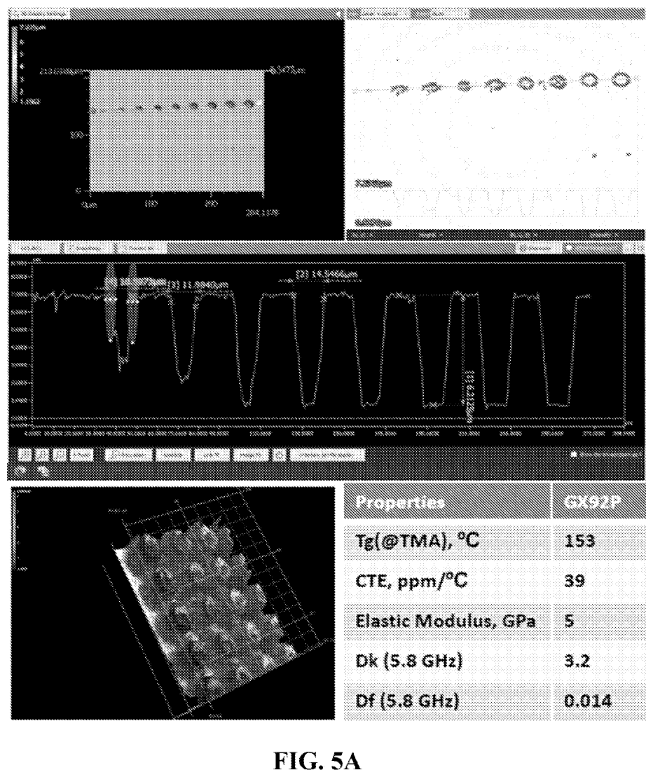

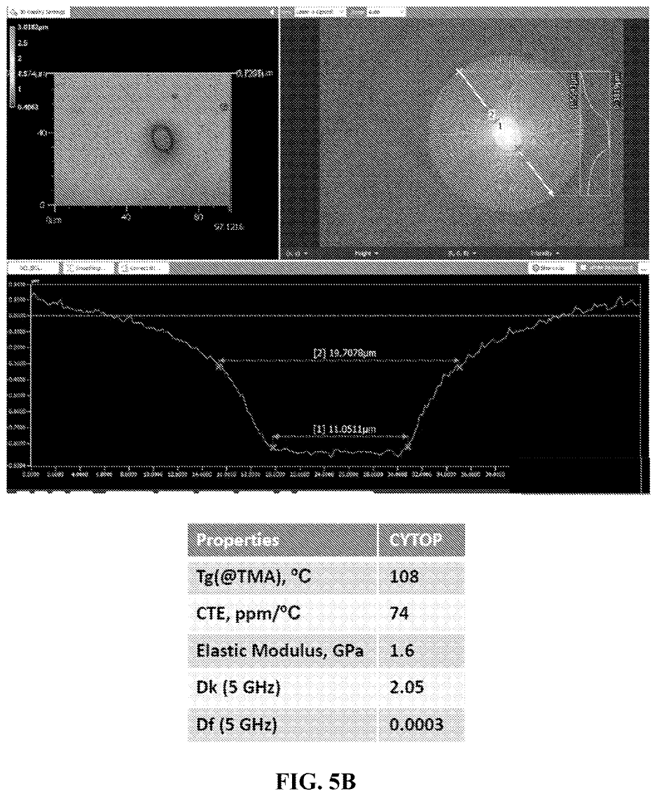

The line scan profile of FIG. 5A confirms concave structure formed by laser ablation of polymer film. FIG. 5A also shows measurements via Scanning Acoustic Microscopy of the fabrication of a concave structure in GX92P, a non-photo-imageable dielectric (non-PID), using a femtosecond laser. In optical microscope image 408, a fabricated set of concave structures is shown. The PID had an exposure dose of 200 mJ/cm². FIG. 5B also shows the mechanical characterization properties of the PID.

Reactive Ion Etching. FIG. 5B shows measurements via optical microscopy of the fabricated structure in CYTOP, a non-photo-imageable dielectric (non-PID), using plasma-thermal reactive ion etching (plasma-therm RIE). The images were acquired using the Keyence 3D optical profiler. The concave structure has a diameter profile between about 11 μm and 19 μm.

### Discussion

In the heterogeneous integration, different components can be stacked on top of each other through high-density vertical interconnections to reduce the signal transmission path and the RC delay. For example, high-bandwidth memory (HBM) realized by the heterogeneous integration of multilayer DRAM chips and processor dies within a single package can provide many benefits, such as high bandwidth, high capacity, low power consumption, and small form factor [2]. To integrate multiple dies, bonding by solder microbumps is widely used in the stacking process of heterogeneous integrated devices due to its low thermal budget, while the interconnection density and bonding yield loss of this method are challenging by the high required volume and the formation of intermetallic layers. To realize 3-D interconnection with finer pitch dimension and higher volume production, Cu-Cu direct bonding without the formation of an intermetallic compound is considered a desirable candidate in alternative bonding technology due to the excellent electrical conductivity, thermal conductivity, and mechanical strength of Cu [4]-[6].

Cu-Cu direct bonding is mainly achieved by the diffusion of Cu atoms during the thermal compression process. A typical Cu-Cu direct bonding process requires a high bonding temperature of about 350° C.-400° C. for a long bonding duration [3]. However, such high temperatures would create a large thermal budget and further damage the component characteristics. In addition, long-term bonding duration leading to high cost and low throughput is impractical for mass production. Therefore, methods to achieve low-temperature bonding process have been proposed and discussed in considerable detail recently, such as Cu nanotwin structures, surface passivation bonding, and surface activated bonding (SAB) [7]-[9]. Though these methods can effectively reduce the bonding temperature and time of Cu-Cu direct bonding, chemical mechanical planarization (CMP) before bonding is necessary for reducing surface roughness. However, CMP has a harsh process tolerance and high fabrication cost. Thus, studies on low-temperature bonding methods with high tolerance on surface roughness are significant for the development of Cu-Cu direct bonding. In previous studies, a design of pillar-concave structure has been proposed to assist low-temperature bonding [10], [11]. In addition, low-temperature Cu bonding with pillar-concave structure has also been successfully preliminarily demonstrated without CMP treatment in previous studies [12], [13] of the inventors. However, bonding mechanism, surface roughness, and reliability tests are still required in detail to verify its feasibility for practical use.

### Additional Discussion

Direct Cu-Cu bonding method gains attention because it has a high possibility of replacing solder ball, which is widely used at the present time in the field of heterogeneous integration of advanced packaging and 3-D integration, such as system in package, package on package [14], fan-out [15]-[17], 2.5-D IC, as well as 3-D IC. High-quality and high-throughput Cu-Cu bonding has critical requirements such as rapid Cu diffusion rate, high cleanliness on Cu bonding surface, and considerable Cu grain growth. Direct Cu-Cu bonding can be achieved at room temperature under ultrahigh vacuum (UHV) at the order of 10-8 torr [18]. In addition to the condition of UHV, the bonding interface must be cleaned using the surface-activated method, which is a time-consuming and expensive process. Therefore, in consideration of quality, cost, as well as yield, effective Cu-Cu bonding at a temperature of 300° C. and higher can be achieved with a bonding duration of 30 min and longer [19]. However, a Cu-Cu bonding process at temperature higher than 300° C. is no longer attractive to the current semiconductor manufacturing industry, which emphasizes low process cost. As a result, low-temperature Cu-Cu direct bonding methods, such as Cu-based direct bonding interconnect (DBI) [6], have been introduced with an interconnect pitch of 25 μm at a bonding temperature of 125° C. In this method, Cu bonding interface must be extremely smooth to achieve bonding at a relatively low temperature, thus demanding the use of chemical mechanical planarization to realize the smooth bonding surface, but this, in turn, leads to a high-cost manufacturing process. In addition to the DBI method, another low-temperature Cu direct bonding method known as insertion bonding can achieve low-temperature Cu bonding at 100° C. on a Si substrate with a silicon dioxide layer, which introduces high shear stress at the Cu pillar and Cu concave contact interface. The localized generated stress leads to the deformation of localized Cu, which provides assistance in the bonding process [11]. However, the implementation of a concave on the dielectric layer requires a photolithography process to define the position of the concave, while a wet anisotropic etching process is required for concave formation. With the mentioned fabrication processes, the insertion bonding is also a protracted Cu-Cu bonding method. Besides that, the insertion bonding on silicon substrate with dielectric layer is less favorable for integration with the existing heterogeneous integration technology such as through-silicon via (TSV).

In contrast, the exemplary Cu pillar-concave structure is successfully demonstrated on silicon with a polymer layer. The polymer material can provide high adhesive strength that can adhere to different substrates, such as printed circuit boards. Besides that, the polymer described herein is highly compatible to the back-end-of-line manufacturing process in the semiconductor industry. The implementation of a pillar-concave structure on silicon with a polymer layer can be carried out at a low temperature of 150° C. for 10 min in atmospheric pressure.

Although example embodiments of the present disclosure are explained in some instances in detail herein, it is to be understood that other embodiments are contemplated. Accordingly, it is not intended that the present disclosure be limited in its scope to the details of construction and arrangement of components set forth in the following description or illustrated in the drawings. The present disclosure is capable of other embodiments and of being practiced or carried out in various ways.

It must also be noted that, as used in the specification and the appended claims, the singular forms “a,” “an,” and “the” include plural referents unless the context clearly dictates otherwise. Ranges may be expressed herein as from “about” or “approximately” one particular value and/or to “about” or “approximately” another particular value. When such a range is expressed, other exemplary embodiments include the one particular value and/or to the other particular value.

By “comprising” or “containing” or “including” is meant that at least the name compound, element, particle, or method step is present in the composition or article or method, but does not exclude the presence of other compounds, materials, particles, method steps, even if the other such compounds, material, particles, method steps have the same function as what is named.

In describing example embodiments, terminology will be resorted to for the sake of clarity. It is intended that each term contemplates its broadest meaning as understood by those skilled in the art and includes all technical equivalents that operate in a similar manner to accomplish a similar purpose. It is also to be understood that the mention of one or more steps of a method does not preclude the presence of additional method steps or intervening method steps between those steps expressly identified. Steps of a method may be performed in a different order than those described herein without departing from the scope of the present disclosure. Similarly, it is also to be understood that the mention of one or more components in a device or system does not preclude the presence of additional components or intervening components between those components expressly identified.

The term “about,” as used herein, means approximately, in the region of, roughly, or around. When the term “about” is used in conjunction with a numerical range, it modifies that range by extending the boundaries above and below the numerical values set forth. In general, the term “about” is used herein to modify a numerical value above and below the stated value by a variance of 10%. In one aspect, the term “about” means plus or minus 10% of the numerical value of the number with which it is being used. Therefore, about 50% means in the range of 45%-55%. Numerical ranges recited herein by endpoints include all numbers and fractions subsumed within that range (e.g., 1 to 5 includes 1, 1.5, 2, 2.75, 3, 3.90, 4, 4.24, and 5).

Similarly, numerical ranges recited herein by endpoints include subranges subsumed within that range (e.g., 1 to 5 includes 1-1.5, 1.5-2, 2-2.75, 2.75-3, 3-3.90, 3.90-4, 4-4.24, 4.24-5, 2-5, 3-5, 1-4, and 2-4). It is also to be understood that all numbers and fractions thereof are presumed to be modified by the term “about.”

The following patents, applications and publications as listed below and throughout this document are hereby incorporated by reference in their entirety herein.
[1] C.-T. Ko and K.-N. Chen, “Wafer-level bonding/stacking technology for 3D integration,” Microelectron. Rel., vol. 50, no. 4, pp. 481-488, Apr. 2010.
[2] H. Jun et al., “HBM (high bandwidth memory) DRAM technology and architecture,” in Proc. IEEE Int. Memory Workshop (IMW), May 2017, pp. 1-4.
[3] R. Reif, C. S. Tan, A. Fan, K.-N. Chen, S. Das, and N. Checka, “3-D interconnects using Cu wafer bonding: Technology and applications,” in Proc. Advanced Metallization Conf., 2002, pp. 37-45.
[4] L. Sanchez et al., “Chip to wafer direct bonding technologies for high density 3D integration,” in Proc. IEEE 62nd Electron. Compon. Technol. Conf. (ECTC), May/Jun. 2012, pp. 1960-1964.
[5] Y. Kagawa et al., “The scaling of Cu-Cu hybrid bonding for high density 3D chip stacking,” in Proc. Electron Devices Technol. Manuf. Conf. (EDTM), Mar. 2019, pp. 297-299.
[6] P. Enquist, G. Fountain, C. Petteway, A. Hollingsworth, and H. Grady, “Low cost of ownership scalable copper direct bond interconnect 3D IC technology for three-dimensional integrated circuit applications,” in Proc. IEEE Int. Conf. 3D Syst. Integr., Sep. 2009, pp. 1-6.
[7] C.-M. Liu et al., “Low-temperature direct copper-to-copper bonding enabled by creep on (111) surfaces of nanotwinned cu,” Sci. Rep., vol. 5, no. 1, p. 09734, Sep. 2015.
[8] Y.-P. Huang, Y.-S. Chien, R.-N. Tzeng, and K.-N. Chen, “Demonstration and electrical performance of Cu-Cu bonding at 150° C. with pd passivation,” IEEE Trans. Electron Devices, vol. 62, no. 8, pp. 2587-2592, Aug. 2015.
[9] T. Suga and F. Mu, “Surface activated bonding method for low temperature bonding,” in Proc. 7th Electron. Syst.-Integr. Technol. Conf. (ESTC), Sep. 2018, pp. 1-4.
[10] N. Tanaka et al., “Through-silicon via interconnection for 3D integration using room-temperature bonding,” IEEE Trans. Adv. Packag., vol. 32, no. 4, pp. 746-753, Nov. 2009.
[11] C. Okoro, R. Agarwal, P. Limaye, B. Vandevelde, D. Vandepitte, and E. Beyne, “Insertion bonding: A novel Cu-Cu bonding approach for 3D integration,” in Proc. 60th Electron. Compon. Technol. Conf. (ECTC), Las Vegas, NV, USA, 2010, pp. 1370-1375.
[12] T.-C. Chou, “Low temperature cu to cu direct bonding in atmosphere environment using pillar-concave structure in 3D integration,” in Proc. Extended Abstr. Int. Conf. Solid State Devices Mater., Sep. 2017, pp. 381-382.
[13] T.-C. Chou et al., “Non-planarization Cu-Cu direct bonding and gang bonding with low temperature and short duration in ambient atmosphere,” in IEDM Tech. Dig., Dec. 2019, p. 5.
[14] M. Dreiza, A. Yoshida, K. Ishibashi, and T. Maeda, “High density PoP (package-on-package) and package stacking development,” in Proc. 57th ECTC, Reno, NV, USA, May/Jun. 2007, pp. 1397-1402.
[15] C. C. Liu et al., “High-performance integrated fan-out wafer level packaging (InFO-WLP): Technology and system integration,” in IEDM Tech. Dig., Dec. 2012, pp. 14.1.1-14.1.4.
[16] D. Yu, “A new integration technology platform: Integrated fan-out wafer level-packaging for mobile applications,” in Proc. Symp. VLSI Technol., vol. 47. Jun. 2015, pp. T46-T47.
[17] H.-W. Liu et al., “Warpage characterization of panel fan-out (P-FO) package,” in Proc. 64th ECTC, May 2014, pp. 1750-1754.
[18] T. H. Kim, M. M. R. Howlader, T. Itoh, and T. Suga, “Room temperature Cu-Cu direct bonding using surface activated bonding method,” J. Vac. Sci. Technol. A, Vac. Surf. Films, vol. 21, no. 2, pp. 449-453, Mar. 2003.
[19] K. N. Chen, C. S. Tan, A. Fan, and R. Reif, “Morphology and bond strength of copper wafer bonding,” Electrochem. Solid-State Lett., vol. 7, no. 1, pp. G 14-G16, 2004.
[20] Yang, Yu-Tao, et al. “Low-temperature Cu-Cu direct bonding using pillar-concave structure in advanced 3-D heterogeneous integration.” IEEE Transactions on Components, Packaging and Manufacturing Technology 7.9 (2017): 1560-1566.
[21] Chou, Tzu-Chieh, et al. “Investigation of Pillar-Concave Structure for Low-Temperature Cu-Cu Direct Bonding in 3-D/2.5-D Heterogeneous Integration.” IEEE Transactions on Components, Packaging and Manufacturing Technology 10.8 (2020): 1296-1303.
[22] J.-Y. Juang et al., “Copper-to-copper direct bonding on highly (111)-oriented nanotwinned copper in no-vacuum ambient,” Sci. Rep., vol. 8, no. 1, Dec. 2018, Art. no. 13910.
[23] T. H. Kim, M. M. R. Howlader, T. Itoh, and T. Suga, “Room temperature Cu-Cu direct bonding using surface activated bonding method,” J. Vac. Sci. Technol., vol. 21, no. 2, pp. 449-453, 2003.
[24] A. K. Panigrahi, T. Ghosh, S. R. K. Vanjari, and S. G. Singh, “Oxidation resistive, CMOS compatible copper-based alloy ultrathin films as a superior passivation mechanism for achieving 150° C. Cu-Cu wafer on wafer thermocompression bonding,” IEEE Trans. Electron Devices, vol. 64, no. 3, pp. 1239-1245, Mar. 2017.
[25] X. Fan, “Wafer level packaging (WLP): Fan-in, fan-out and three-dimensional integration,” in Proc. 11th Int. Thermal, Mech. Multi-Phys. Simulation, Bordeaux, France, Apr. 2010, pp. 1-7.
[26] C.-F. Tseng, C.-S. Liu, C.-H. Wu, and D. Yu, “InFO (wafer level integrated fan-out) technology,” in Proc. IEEE 66th Electron. Compon. Technol. Conf. (ECTC), May 2016, pp. 1-6.
[27] T. Braun et al., “From fan-out wafer to fan-out panel level packaging,” in Proc. Eur. Conf. Circuit Theory Des. (ECCTD), vol. 2015, pp. 1-4.
[28] S. Ahn et al., “Wafer level multi-chip gang bonding using TCNCF,” in Proc. IEEE 66th Electron. Compon. Technol. Conf. (ECTC), May 2016, pp. 923-928.
[29] U. Andrade, M. A. Meyers, K. S. Vecchio, and A. H. Chokshi, “Dynamic recrystallization in high-strain, high-strain-rate plastic deformation of copper,” Acta Metall. Mater., vol. 42, no. 9, pp. 3183-3195, Aug. 1994.
[30] M. J. M. Abadie, High Performance Polymers—Polyimides Based—From Chemistry to Applications. Rijeka, Croatia: InTech, 2012.
[31] J. Yota et al., “Variable frequency microwave and convection furnace curing of poly benzoxazole buffer layer for GaAs HBT technology,” IEEE Trans. Semicond. Manuf., vol. 20, no. 3, pp. 323-332, Aug. 2007.
[32] D. N. Khanna and W. H. Mueller, “New high temperature stable positive photoresists based on hydroxy polyimides and polyamides containing the hexafluoroisopropylidene (6-f) linking group,” Polym. Eng. Sci., vol. 29, no. 14, pp. 954-959, Aug. 1989.
[33] R. Jensen, J. Cummings, and H. Vora, “Copper/polyimide materials system for high performance packaging,” IEEE Trans. Compon., Hybrids, Manuf. Technol., vol. 7, no. 4, pp. 384-393, Dec. 1990.
[34] N. Kumbhat et al., “Highly-reliable, 30 μm pitch copper interconnects using nano-ACF/NCF,” in Proc. IEEE 59th Electron. Compon. Technol. Conf., May 2009, pp. 1479-1485.
[35] C.-J. Zhan, C.-C. Chuang, J.-Y. Juang, S.-T. Lu, and T.-C. Chang, “Assembly and reliability characterization of 3D chip stacking with 30 μm pitch lead-free solder micro bump interconnection,” in Proc. IEEE 60th Electron. Compon. Technol. Conf., Jun. 2010, pp. 1043-1049.

1. A semiconductor device comprising:
a plurality of hybrid-bonding interconnection structures each formed by placing (i) a nano-copper concave structure embedded in a first bonding polymer layer onto (ii) a non-planar protruding Cu structure embedded in a second polymer bonding layer, wherein a pitch distance between each of the plurality of hybrid-bonding interconnection structure is less than 5 um.

2. The semiconductor device of claim 1, wherein the nano-copper concave structure and the non-planar Cu structure form a Cu-Cu bonding at a low bonding temperature of less than 150°C.

3. The semiconductor device of claim 1, wherein the non-planar protruding Cu structure forms a pillar for insertion into the nano-copper concave structure.

4. The semiconductor device of claim 1, wherein the bonding polymer layer comprises a low-temperature cure dielectric polymer.

5. The semiconductor device of claim 1, wherein the bonding polymer layer comprises a non-polymer dielectric.

6. The semiconductor device of claim 1, wherein the nano-copper concave structure embedded in the dielectric is fabricated at least in part using photolithography and a maskless aligner tool in combination with a photosensitive polymer.

7. The semiconductor device of claim 1, wherein the nano-copper concave structure embedded in the dielectric is fabricated at least in part using laser drilling of a non-photosensitive polymer.

8. The semiconductor device of claim 1, wherein the first bonding layer is made of a first material, wherein the second bonding layer is made of a second material, wherein the first material and the second material are the same.

9. The semiconductor device of claim 8, wherein the first material and the second material comprise a B-stageable/Photo imageable polymer or a photo imageable dielectric (PID).

10. The semiconductor device of claim 8, wherein the first material and the second material comprise at least one of polyimide (PI), polybenzoxazole (PBO), benzocyclobutene (BCB), Benzocyclobutene-modified silsesquioxane (BCB-POSS), polyimide silsesquioxane (PI-POSS), epoxy, acrylated polymers, or hybrid sol-gels.

11. The semiconductor device of claim 1, wherein the plurality of hybrid-bonding interconnection structures are employed for chip-on-chip interconnect.

12. The semiconductor device of claim 1, wherein the plurality of hybrid-bonding interconnection structures are employed for chip-on-wafer interconnect.

13. The semiconductor device of claim 1, wherein the plurality of hybrid-bonding interconnection structures are employed for chip-on-glass panels interconnect.

14. The semiconductor device of claim 1, wherein the plurality of hybrid-bonding interconnection structures are employed for chip-on-organic substrate interconnect.

15. The semiconductor device of claim 1, wherein the plurality of hybrid-bonding interconnection structures are employed for wafer-on-wafer interconnect.

16. The semiconductor device of claim 1, wherein the plurality of hybrid-bonding interconnection structures are employed for wafer-on-glass interconnect.

17. The semiconductor device of claim 1, wherein the plurality of hybrid-bonding interconnection structures are employed for glass-on-glass interconnect.

18. The semiconductor device of claim 1, wherein the nano-copper concave structure and the non-planar protruding Cu structure each includes (111) nano-twinned Cu surfaces having high surface diffusivity and low oxidation rate.

19. A method to fabricate a first portion of an interconnection structure, the method comprising:
coating a dielectric layer on a substrate;
forming patterned portions of the dielectric layer;
coating a patterned sacrificial layer over at least a portion of non-patterned portions;
depositing a copper-based layer by glance angle deposition or electrodeposition to form a nano-copper concave structure embedded in a first bonding polymer layer; and
removing the patterned sacrificial layer,
wherein the nano-copper concave structure is contacted with a non-planar protruding Cu structure embedded in a second polymer bonding layer to form a hybrid-bonding interconnection structure.

20. A method to fabricate a first portion of an interconnection structure, the method comprising:
coating a dielectric layer on a substrate;
removing, via a laser machining operation, portions of the dielectric layer to form a nano-copper concave structure embedded in a first bonding polymer layer,
wherein the nano-copper concave structure is contacted with a non-planar protruding Cu structure embedded in a second polymer bonding layer to form a hybrid-bonding interconnection structure.

21-26. (canceled)
